(19) United States
(12) Patent Application Publication
(10) Pub. No.: US 2022/0187351 A1
(43) Pub. Date: Jun. 16, 2022

(54) WAVEFORM MEASURING METHOD

(71) Applicant: NANJING MACROTEST SEMICONDUCTOE TECHNOLOGY CO., LTD., Nanjing (CN)

(72) Inventor: GUOLIANG MAO, Nanjing (CN)

(21) Appl. No.: 17/653,455

(22) Filed: Mar. 3, 2022

Related U.S. Application Data
(63) Continuation of application No. PCT/CN2020/124070, filed on Oct. 27, 2020.

(30) Foreign Application Priority Data
Nov. 12, 2019 (CN) 201911098085.0

(51) Int. Cl. G01R 23/10

(52) U.S. Cl. CPC G01R 23/10

(57) ABSTRACT

The present invention discloses a waveform measuring method. It converts the waveform to be measured into two corresponding square waves by two comparators. When the hardware logic device receives the signal from the host computer software to start waveform acquisition, it acquires two square waves and simultaneously starts the counter to count with a fixed high frequency clock. When the waveform is flipped, if the count value is less than the set filter value, the waveform is filtered out; if the count value is greater than the set filter value, the hardware logic device saves the waveform and count value and clears the counter to zero. The number of waveform flips is judged whether the set value is reached, and if not, the count is recounted; if it is reached, the waveform acquisition is stopped, and then the waveform and count values saved by the hardware logic device are read and optimized by the host computer software. According to the test requirements, the corresponding algorithm is executed, and the calculation results are output. It improves the accuracy and precision of the measurement and increases the flexibility of the measuring method.

### CROSS-REFERENCE TO RELATED APPLICATIONS

This application is a continuation of International Patent Application Number PCT/CN2020/124070, filed on Oct. 27, 2020, which claims the benefit and priority of Chinese Patent Application Number 201911098085.0, filed on Nov. 12, 2019 with China National Intellectual Property Administration, the disclosures of which are incorporated herein by reference in their entireties.

### FIELD OF THE INVENTION

The present invention relates to the field of electronics, and in particular to a waveform measuring method.

### BACKGROUND OF THE RELATED ART

The current technology for waveform measurement is to provide multiple measurement gears and a choice of measurement function modes. Users should select their own measurements according to the frequency cycle of the signal to be measured and the desired measurement items. Measurement gears include 1K, 10K, 100K, 1M, etc. The measurement function modes include frequency, cycle, duty cycle, rise/fall with time, and interval time between signals. When measuring a signal with a long cycle, some of the high frequency information of the signal will be lost; waveforms with variable frequency during the cycle cannot be accurately identified and measured; unstable measurement of signals with very low duty cycle makes the measurement results inaccurate and reliable, and the flexibility of data processing insufficient.

### SUMMARY OF THE INVENTION

The present invention provides a waveform measuring method that improves the accuracy and precision of measurement results and increases the flexibility of data processing.

To achieve the above, the present invention provides a waveform measuring method comprising:

Receive the start waveform acquisition signal from the host computer software for waveform acquisition.

Start the counter to count at a fixed high frequency clock.

When the waveform is flipped, judge whether the count value is greater than the set filter value.

Judge whether the number of waveform flips reaches the set value.

Read the waveform through the host computer software and output the measurement results.

Where, when the host computer software issues a signal to start waveform acquisition, the method includes:

Input the waveform to be measured into the first comparator and the second comparator, convert it into two corresponding square waves, and transfer the converted square waves to the hardware logic device.

Where, judging whether the count value is greater than the set filter value, comprising:

If the count value is less than the set filter value, the waveform is invalid and is filtered out.

If the count value is greater than the set filter value, the hardware logic device saves the waveform and count value, and clears the counter to zero.

Where, judging whether the number of waveform flips reaches the set value, comprising:

If the number of waveform flips does not reach the set value, the counter will recount.

If the number of waveform flips reaches the set value, the hardware logic device stops the waveform acquisition.

Where, after the hardware logic device stops the waveform acquisition, the method further comprises:

The host computer software reads the waveforms and count values saved by the hardware logic device and optimizes them.

Where, before outputting the measurement results, the method further comprises:

Calculate the sum of the maintenance times within the cycle to get the waveform cycle parameter, starting with the first comparator from the first state to the second state to its next first state to the second state as a cycle.

Where, before outputting the measurement results, the method further comprises:

Get the maintenance time of the corresponding state as the waveform rise parameter with time when the first comparator is the first state, the second comparator is the second state, and the first comparator is the second state in the previous state.

Where, before outputting the measurement results, the method further comprises:

Get the maintenance time of the corresponding state as the waveform fall parameter with time when the first comparator is the first state, the second comparator is the second state, and the first comparator is the first state in the previous state.

The present invention provides a waveform measuring method. Convert the waveform to be measured into two corresponding square waves by two comparators. When the hardware logic device receives the signal from the host computer software to start waveform acquisition, start the counter to count at a fixed high frequency clock. When the waveform is flipped, if the count value is less than the set filter value, the waveform is invalid and is filtered out; if the count value is greater than the set filter value, the hardware logic device saves the waveform and count value, and clears the counter to zero. Judge whether the number of waveform flips reaches the set value. If it is not reached, the waveform is recounted; if it is reached, the waveform acquisition is stopped. The host computer software reads the waveforms and count values saved by the hardware logic device and optimizes them. According to the test requirements, the corresponding algorithm is executed, and the calculation results are output.

### BRIEF DESCRIPTION OF THE DRAWINGS

In order to more clearly illustrate the technical solutions in the embodiments or prior art of the invention, the following is a brief description of the attached drawings that are required to be used in the description of the embodiments or prior art. Obviously, the attached drawings in the following description are only some embodiments of the present invention, and other drawings may be obtained from these attached drawings without creative effort by a person of ordinary skill in the art.

FIG. 1 is a method flow diagram of a waveform measuring method provided by the present invention.

FIG. 2 is a flow diagram of a waveform measuring method provided by the present invention.

FIG. 3 is a schematic diagram of a waveform measurement provided by the present invention.

### DESCRIPTION OF THE INVENTION

The embodiments of the present invention are described in detail below. Examples of the described embodiments are shown in the attached drawings. Where the same or similar label from beginning to end indicates the same or similar components or components with the same or similar function. The embodiments described below by the attached drawings are exemplary and are intended to illustrate the present invention and are not to be construed as limiting the present invention.

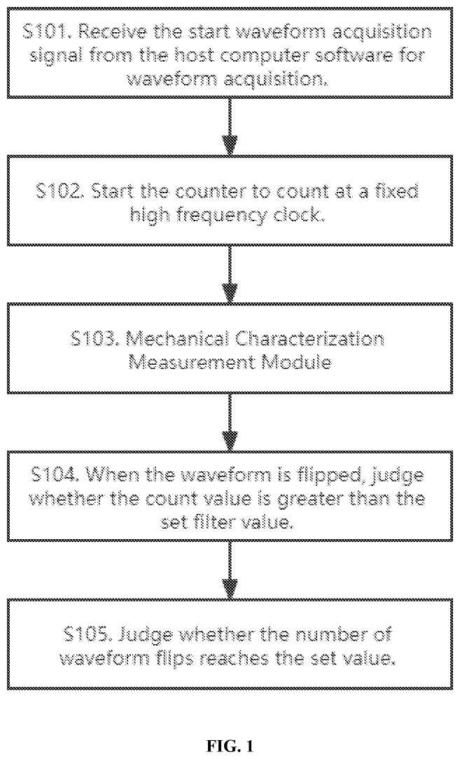

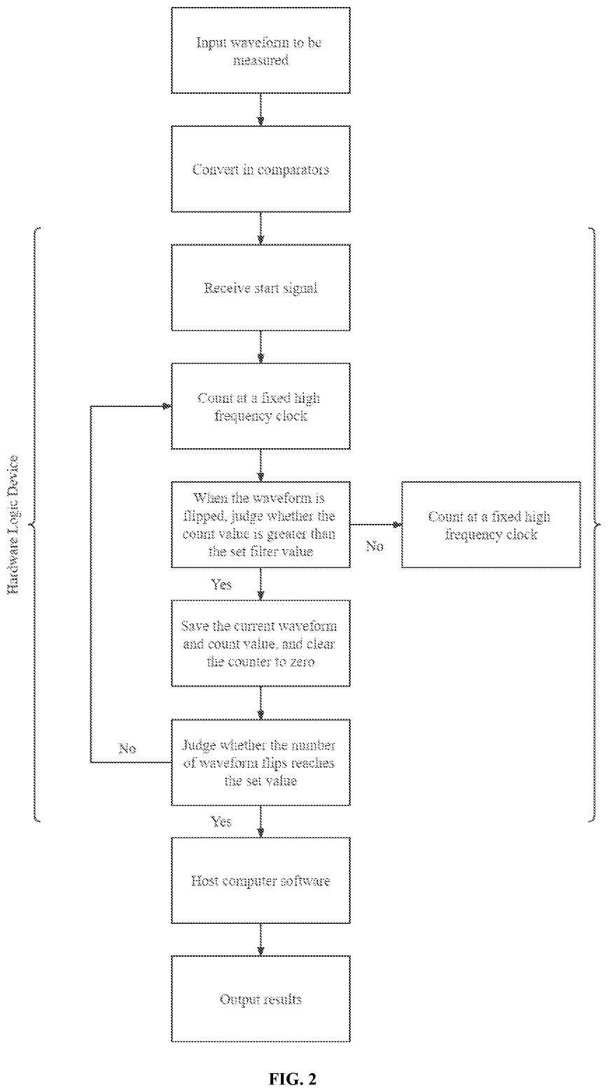

Referring to FIGS. 1 and 2, the present invention provides a waveform measuring method comprising:

S101. Receive the start waveform acquisition signal from the host computer software for waveform acquisition.

Convert the waveform to be measured into two corresponding square waves by the first comparator and the second comparator. When the hardware logic device receives the signal from the host computer software to start waveform acquisition, it acquires two corresponding square waves that are converted by two comparators respectively for subsequent observation and calculation.

S102. Start the counter to count at a fixed high frequency clock.

When the hardware logic device receives the signal to start waveform acquisition, it starts the counter, and the counter counts at a fixed high frequency accumulation. Fixed high resolution measurements allow all signals to be measured through a fixed high frequency. The measured resolution will not be affected by the signal to be measured. Low-interval cycle acquisition measurements avoid losing some information or failing to accurately identify and measure, ensuring measurement accuracy and precision.

S103. When the waveform is flipped, judge whether the count value is greater than the set filter value.

When the waveform is flipped, it is necessary to judge whether the count value is greater than the set filter value. If the count value is less than the set filter value, the waveform is invalid and is filtered out. If the count value is greater than the set filter value, the hardware logic device saves the waveform and count value, and clears the counter to zero. Continue to acquire waveforms.

S104. Judge whether the number of waveform flips reaches the set value.

After each waveform flip, it is necessary to judge whether the accumulated number of waveform flips reaches the set value. If it does not reach the set value, it returns to the second step to count and judge again; if it reaches the set value, the hardware logic device stops waveform acquisition, saves all waveforms and count values that reach the requirements, and waits for the host computer software to read the data. The design of the hardware logic devices is simpler than the original technology, and the internal resources are less occupied.

S105. Read the waveform through the host computer software and output the measurement results.

The host computer software reads the waveforms and data saved by the hardware logic device for further filtering, interception, and other optimization processes. The completed optimized waveforms are sent to the corresponding algorithms according to the test requirements. The comparator data set for the corresponding state is selected to calculate the measurement result based on the corresponding count value. Instead of solidifying the waveform in a hardware logic device, it relies on the hardware logic device to completely record the waveform to be measured after the comparator. By setting the range of filtered burrs and jitter as required, the hardware logic device will automatically filter out these spurious waves and return a clean, complete waveform to the host computer with invalid information already filtered out. The mode and method of measurement no longer must be changed depending on the signal to be measured, increasing the flexibility of data processing.

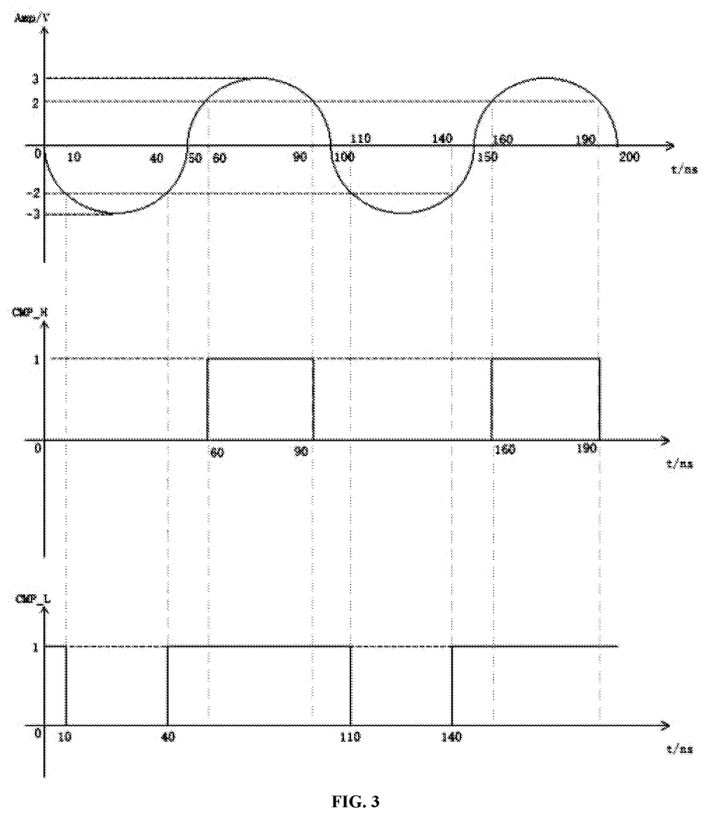

See FIG. 3. The waveform to be measured is like the sine wave shown in FIG. 3 (amplitude −3V to +3V, cycle 100 ns). It is compared by two comparators CMPH and CMPL. The threshold level of CMPH is set to 2V and the threshold level of CMPL is set to −2V. The waveforms to be measured are shown in the second and third parts of FIG. 3 after the two comparators. The hardware logic device is set to acquire waveforms at a fixed 400 MHZ (i.e., 2.5 ns cycle) starting from the 0 moment. The format of the recorded data is set to: {CMPH, CMPL}_count value.

After the waveform acquisition is completed, the raw waveform data received by the host computer software is as follows:
1) 01_0100, 2) 00_1100, 3) 01_1000, 4) 11_1100, 5) 01_1000, 6) 00_1100, 7) 01_1000, 8) 11_1100, 9) 01_0100.

The data represent the following meanings:
1) {CMPH, CMPL} is the state of 01, the count value is 4, which means that the state is maintained for 10ns.
2) {CMPH, CMPL} is the state of 00, the count value is 12, which means that the state is maintained for 30ns.
3) {CMPH, CMPL} is the state of 01, the count value is 8, which means that the state is maintained for 20ns.
4) {CMPH, CMPL} is the state of 11, the count value is 12, which means that the state is maintained for 30 ns.
5) {CMPH, CMPL} is the state of 01, the count value is 8, which means that the state is maintained for 20ns.
6) {CMPH, CMPL} is the state of 00, the count value is 12, which means that the state is maintained for 30ns.
7) {CMPH, CMPL} is the state of 01, the count value is 8, which means that the state is maintained for 20ns.
8) {CMPH, CMPL} is the state of 11, the count value is 12, which means that the state is maintained for 30ns.
9) {CMPH, CMPL} is the state of 01, the count value is 4, which means the state is maintained for 10ns.

The cycle parameter of the waveform in this segment is calculated on the PC as follows:

The start of CMPL from 1 to 0 state to its next 1 to 0 state can be considered as one cycle. In the above data, one cycle starts from the 2nd set of states to the 5th set of data states. The whole maintenance time (cycle) is: 30+20+30+20=100ns. The calculated results can accurately reflect the waveform parameters.

The rise of the waveform in this segment from −2V to 2V with time is calculated on the PC as follows:

The rise from −2V to 2V with time is equivalent to: the maintenance time of the state where CMPL is 1 and CMPH is 0. CMPL must be 0 in the previous state. −2V to 2V rise with time in the above data (3rd or 7th data set): 20ns. The calculated results can accurately reflect the waveform parameters. The fall of the waveform in this segment from 2V to −2V with time is calculated on the PC as follows:

The fall from 2V to −2V with time is equivalent to: the maintenance time of the state with CMPL of 1 and CMPH of 0. CMPL must be 1 in the previous state. 2V to −2V fall time in the above data (5th data set) is: 20ns. The present invention provides a waveform measuring method. Convert the waveform to be measured into two corresponding square waves by two comparators. When the hardware logic device receives the signal from the host computer software to start waveform acquisition, it acquires the two square waves of the completed conversion. Start the counter to count at a fixed high frequency clock. When the waveform is flipped, if the count value is less than the set filter value, the waveform is invalid and is filtered out; if the count value is greater than the set filter value, the hardware logic device saves the waveform and count value, and clears the counter to zero. Judge whether the number of waveform flips reaches the set value. If it is not reached, the waveform is recounted; if it is reached, the waveform acquisition is stopped. The host computer software reads the waveforms and count values saved by the hardware logic device and optimizes them. According to the test requirements, the comparator data set of the corresponding state is selected to calculate the corresponding result based on the corresponding count value. The hardware logic device records the current waveform at a fixed high resolution and returns it to the host computer, which does the final data analysis and processing. The mode and method of measurement no longer must be changed according to the signal to be measured, making the measurement more accurate and adaptable. Data processing is also becoming more flexible, rapid and intuitive.

The above disclosed is only a preferred embodiment of the present invention and cannot be used to limit the scope of the present invention. Equivalent changes made by a person of ordinary skill in the art based on an understanding to implement all or part of the processes of the above embodiments and in accordance with the claims of the invention remain within the scope of the invention.

I claim:

1. A waveform measuring method, characterized in that it comprises: receive the start waveform acquisition signal from the host computer software for waveform acquisition; start the counter to count at a fixed high frequency clock;
when the waveform is flipped, judge whether the count value is greater than the set filter value; judge whether the number of waveform flips reaches the set value;
read the waveform through the host computer software and output the measurement results.

2. A waveform measuring method as claimed in claim 1, characterized in that the host computer software issues a start waveform acquisition signal to acquire waveforms, comprising: input the waveform to be measured into the first comparator and the second comparator, convert it into two corresponding square waves, and transfer the converted square waves to the hardware logic device.

3. A waveform measuring method as claimed in claim 1, characterized in that judging whether the count value is greater than the set filter value, comprising:
if the count value is less than the set filter value, the waveform is invalid and is filtered out; if the count value is greater than the set filter value, the hardware logic device saves the waveform and count value, and clears the counter to zero.

4. A waveform measuring method as claimed in claim 3, characterized in that judging whether the number of waveform flips reaches the set value, comprising: if the number of waveform flips does not reach the set value, the counter will recount; if the number of waveform flips reaches the set value, the hardware logic device stops the waveform acquisition.

5. A waveform measuring method as claimed in claim 4, characterized in that after the hardware logic device stops waveform acquisition, the method further comprises: the host computer software reads the waveforms and count values saved by the hardware logic device and optimizes them.

6. A waveform measuring method as claimed in claim 1, characterized in that before outputting the measurement results, the method further comprises:
calculate the sum of the maintenance times within the cycle to get the waveform cycle parameter, starting with the first comparator from the first state to the second state to its next first state to the second state as a cycle.

7. A waveform measuring method as claimed in claim 1, characterized in that before outputting the measurement results, the method further comprises: get the maintenance time of the corresponding state as the waveform rise parameter with time when the first comparator is the first state, the second comparator is the second state, and the first comparator is the second state in the previous state.

8. A waveform measuring method as claimed in claim 1, characterized in that before outputting the measurement results, the method further comprises: get the maintenance time of the corresponding state as the waveform fall parameter with time when the first comparator is the first state, the second comparator is the second state, and the first comparator is the first state in the previous state.
